(19) United States
(12) Patent Application Publication
(10) Pub. No.: US 2026/0267218 A1
(43) Pub. Date: Sep. 10, 2026

(54) NANOFIBER PELLICLE FILM PRODUCTION AND APPARATUS

(71) Applicant: LINTEC OF AMERICA, INC., Plano, TX (US)

(72) Inventor: Marcio D. LIMA, Richardson, TX (US)

(73) Assignee: LINTEC OF AMERICA, INC., Plano, TX (US)

(21) Appl. No.: 19/167,650

(22) PCT Filed: Mar. 19, 2024
(86) PCT No.: PCT/US2024/020570

§ 371 Date: Sep. 22, 2025

Related U.S. Application Data
(60) Provisional application No. 63/454,429, filed on Mar. 24, 2023.

(51) Int. Cl. G03F 1/62; D04H 1/4382; D04H 1/732

(52) U.S. Cl. CPC G03F 1/62; D04H 1/43838; D04H 1/732; D10B 2505/00

(57) ABSTRACT

An apparatus and method of producing nanofiber pellicle films. A suspension of nanofibers is passed through a filter to produce a thin, preferably ultra-thin, nanofiber pellicle film. The film is floated off of the filter and is adhered to a harvesting frame which can be easily handled. The film may be dried and stored for further processing.

### CROSS REFERENCE TO RELATED APPLICATIONS

This Application claims priority, pursuant to 35 U.S.C. § 119(e) to U.S. Provisional Application No. 63/454,429 filed on Mar. 24, 2023, the contents of which are hereby incorporated by reference in its entirety.

### TECHNICAL FIELD

The present disclosure relates generally to nanofiber pellicle films and, specifically, to a method, apparatus, and system for the production of nanofiber pellicle films.

### BACKGROUND

Nanofibers and nanotubes are known to have unusual mechanical, optical, and electronic properties. Nanotubes, including carbon nanotubes and boron nitride nanotubes, can be formed into a variety of materials, including nanotube fibers, nanotube yarns, nanotube forests, and nanotube sheets or films. These materials can provide useful properties for various applications but can be difficult to produce in quantity.

### SUMMARY

In a first example, Example 1, a method of preparing a nanofiber film includes filtering a collection of nanofibers or nanotubes onto a filter, the filter positioned in a first planar orientation on a bottom of a reservoir, preferably horizontal, to produce a layer of nanofibers or nanotubes (also refer to as a nanofiber film hereafter), tilting the filter to a second planar orientation, the second planar orientation having an inclined angle of at least three degrees from the first planar orientation, and immersing the filter with the layer of nanofiber film atop into a fluid starting at the lowest point of the filter to separate the layer of nanofibers from the filter.

Example 2 includes the subject matter of Example 1, wherein the nanofibers are filtered from a nanofiber suspension, and the nanofiber suspension comprises a fluid.

Example 3 includes the subject matter of Example 2, wherein the fluid is selected from water, an aprotic polar solvent, isopropyl alcohol (IPA), or combinations thereof.

Example 4 includes the subject matter of Example 1, wherein the nanofibers are selected from at least one of carbon nanotubes, boron nitride nanotubes, carbon nanofibers, various nanofibers, or a combination thereof.

Example 5 includes the subject matter of Example 2, wherein the nanofiber suspension comprises at least one nanoparticle.

Example 6 includes the subject matter of any of the preceding Examples, wherein the nanofibers are randomly oriented on the filter and form an interconnected network.

Example 7 includes the subject matter of any of the preceding Examples, and further includes floating the layer of nanofibers away from the filter.

Example 8 includes the subject matter of Example 1, wherein the fluid surface rises steadily, and the fluid surface is applied to separate the layer of nanofibers from the filter.

Example 9 includes the subject matter of Example 8, wherein the steady rising fluid surface eventually submerges the top edge of the layer of nanofibers and separates the layer of nanofibers from the filter completely.

Example 10 includes the subject matter of Example 1, wherein the filter with the layer of nanofibers atop are dipped into a fluid with at least a three-degree angle from horizontal to separate the layer of nanofibers from the filter.

Example 11 includes the subject matter of any of the preceding Examples, wherein tilting the filter to a second planar orientation includes tilting a bottom of a reservoir together with the filter.

Example 12 includes the subject matter of Example 11, wherein at least one drain at the bottom of the reservoir allows communication between the interior and exterior of the reservoir.

Example 13 includes the subject matter of Example 11, wherein the bottom of the reservoir has a plurality of openings forming a shape, the openings being selected from, including, but not limited to, a rounded shape, a square, a rectangular, a polygon, an open or closed circle, a honeycomb, an array of any of the above combination, the shape according to the layer of nanofibers being selected from any shape described above. The bottom of the reservoir may have any shape with a collection of various individual solid geometric shapes described above with voided surroundings and underneath support structures. A preferred shape may be a rectangular shape with a length and a width equal to or greater than 100 mm×120 mm, 110 mm×144 mm, 125 mm×160 mm, 220 mm×140 mm, or 110 mm×280 mm. Another preferred shape may be a circle with a diameter of larger than 14 cm (~6 inches), 20 cm (~8 inches), 30 cm (~12 inches), or 38 cm (~15 inches).

Example 14 includes the subject matter of any preceding Examples, and further includes lifting the layer of nanofibers from the surface of a fluid.

Example 15 includes the subject matter of any of the preceding Examples, wherein the fluid reservoir base has a shape corresponding to the shape of the filter or is different from the shape of the filter but is sufficiently large to accommodate the shape of the filter.

Example 16 includes the subject matter of Example 14 and further includes drying the layer of nanotubes.

Example 17 includes the subject matter of Example 16, wherein the drying method includes, but is not limited to, air drying, vacuum dry, and thermal radiation dry.

Example 18 includes the subject matter of any of the preceding Examples, wherein at least a portion of the layer of nanofibers or the full layer of nanofibers is floated to a surface of a fluid after removal from the filter.

Example 19 is an apparatus including a structural frame with a base, a liquid reservoir pivotally mounted on the base, the liquid reservoir defining a drain, at least one opening in the reservoir bottom, which is in communication with the drain, at least two fluid feeding lines, and a film harvesting mechanism.

Example 20 includes the subject matter of Example 19, wherein a first one of the at least two fluid feeding lines is in communication with a supply of a suspension of nanofibers, and a second one of the at least two fluid feeding lines is in communication with a fluid supply.

Example 21 includes the subject matter of Example 20, wherein the fluid supply comprises water.

Example 22 includes the subject matter of Example 19, wherein at least one opening is a plurality of holes arranged in a shape, while each of the plurality of holes is in communication with the reservoir and the drain.

Example 23 includes the subject matter of Example 22, wherein the shape includes, but are not limited to, a square, a rectangular, any polygon, a round disc, any irregular shape, an array, or arrays of any above-mentioned shapes.

Example 24 includes the subject matter of Example 19, wherein the at least one opening comprises a plurality of small geometric shapes surrounded by voided spaces, the geometric shapes having underneath supporting structures.

Example 25 includes the subject matter of Example 19, wherein the drain has a connection to vacuum pressure.

Example 26 includes the subject matter of Example 25, wherein the vacuum pressure is actively monitored and regulated to accommodate one or more Examples.

Example 27 includes the subject matter of any of Examples 19, wherein the pivotally mounted reservoir is constructed and arranged to be pivoted hydraulically.

Example 28 includes the subject matter of Example 27, wherein the hydraulic power is provided by the same source of water pressure as one of the at least two fluid feeding lines.

Example 29 includes the subject matter of Example 19, wherein the film harvesting mechanism includes a harvesting frame, a harvesting frame holder, a harvesting frame holder track, and a harvesting frame controller.

Example 30 includes the subject matter of Example 29, wherein the harvesting frame holder holds the harvesting frame and maintains the harvesting frame with an inclined angle selected from 3 degrees to 177 degrees from horizontal, preferably an angle selected from 85 degrees to 95 degrees from horizontal, or in a vertical position.

Example 31 includes the subject matter of Example 29, wherein the harvesting frame holder track comprises, in order, a first end, a straight portion, an extension portion, and a second end opposite of the first end. The first end of the harvesting frame holder track is spaced apart from the reservoir bottom. The second end of the harvesting frame holder track is connected to or in close vicinity to a storage space, a film transferring device for transferring a majority of the film to a new frame, a quality control analyzer, a device for further film processing, such as a film coating device, a film annealing device, or a combination thereof.

The straight portion of the harvesting frame holder track may have a vertical position or an angle between 25 degrees to 165 degrees from horizontal. The extension portion of the harvesting frame holder track may have straight, curved, inclined, or descending designs for transporting a harvesting frame from a filtration apparatus to any other analyzers and film processing devices.

Example 32 includes the subject matter of Example 29, wherein the harvesting frame has 1) a closed central opening having a shape to accommodate and accept a film with a shape based on a design of the at least one opening on the floor or bottom of the reservoir to cover the closed central opening, 2) at least one flange for attachment to the harvesting frame holder, and 3) one side of the harvesting frame selected for the initial attachment of a floating layer of nanofibers without any hindrance (the design the flange should not hinder such initial attachment).

Example 33 is a method of preparing a nanofiber film including placing a filter on the bottom of a reservoir, filling the reservoir with a nanofiber suspension and a fluid, filtering at least a portion of the nanotube suspension through the at least one opening at the reservoir bottom by opening a reservoir drain with and without vacuum assistance which connects to the drain, removing nanofibers from the diluted suspension with a filter, the filter having communication with the reservoir drain, and forming a nanofiber film, that is also referred to as a layer of nanofibers, a layer of nanotubes, or a nanotube film, on a surface of the filter.

Example 34 includes the subject matter of Example 33, and further includes tilting the filter or the filter together with the bottom of the reservoir.

Example 35 includes the subject matter of Example 34, and further includes separating the nanofiber film from the filter.

Example 36 includes the subject matter of Examples 33-35, wherein the nanofiber film is separated from the filter using a fluid.

Example 37 includes the subject matter of Example 36, wherein the fluid used for the separation of the nanofiber film from the filter is the same fluid used to dilute the nanofiber suspension during the filtering process.

Example 38 includes the subject matter of Example 36, and further includes floating the nanofiber film at the surface of the fluid after it is separated from the filter.

Example 39 includes the subject matter of Example 34, wherein tilting allows the fluid to impact the nanofiber film starting at its lowest point with the rising fluid surface, which changes the hydrophobic-hydrophilic interface between the nanofiber film and the filter.

Example 40 includes the subject matter of Example 33, and further comprises dipping the nanofiber film on the filter into a fluid with an angle from horizontal, wherein the dipping impact the nanofiber film starting at its lowest point with the surface of the fluid.

Example 41 includes the subject matter of Example 40, wherein the fluid used for separation may be the same fluid for the filtration process.

Example 42 includes the subject matter of Example 34 or Example 40, wherein either the tilting or the dipping of a nanofiber film and a filter includes shifting from horizontal planar to a minimum of 3, 5, 10, 15, 20, 25, or 30 degrees from horizontal (inclined angle).

Example 43 includes the subject matter of Examples 35 to 42, and further includes floating the nanofiber film separated from the filter and ascending (or rising) it to an upper portion of the reservoir.

Example 44 includes the subject matter of any of the preceding Examples 33-43, and further includes depositing the nanofiber film on a harvesting frame by submerging a harvesting frame underneath the fluid surface in an upright position without disturbing the floating nanofiber film, positing the harvesting frame by moving it underneath the nanofiber film across a portion of the nanofiber film, lifting the harvesting frame to allow a first attachment between the top side of the harvesting frame and the nanofiber film and subsequent attachment of the nanofiber film to the side of the harvesting frame with a central opening until the harvesting frame is above the fluid surface and out of the reservoir.

Example 45 includes the subject matter of Example 44, wherein the upright position of the harvesting frame may comprise an angle from 30 degrees to 150 degrees from horizontal, preferably from 85 degrees to 95 degrees or 90 degrees.

Example 46 includes the subject matter of any of the preceding Examples 1-45 and further comprises at least one nanofiber analytic device.

Example 47 includes the subject matter of Example 47, wherein a nanofiber analytic device is selected from a Ramen spectroscope, a particle analyzer or a particle monitor, or a combination thereof.

Example 48 includes the subject matter of any of Examples 1-45 and further comprises at least one nanofiber film analyzer.

Example 49 includes the subject matter of Example 48, wherein the nanofiber film analyzer is selected from a nanofiber film strength analyzer, film deflection measuring apparatus, film deflection adjusting apparatus, film electrical resistance measuring apparatus, a light transmission measuring device with a light spectrum selected from 1 nm to 1 mm, a light transmission mapping device, a light transmission map analyzer, a UV-Vis spectrometer, a Fourier-transform infrared spectrometer, or a combination thereof.

Example 50 includes the subject matter of any of Examples 1-45 and further comprises a nanofiber or nanofiber film processing device.

Example 51 includes the subject matter of Example 50, wherein the nanofiber or nanofiber sheet processing device is selected from a film strength adjustment apparatus, an annealing device, a coating device, or a combination thereof.

Example 52 includes the subject matter of Example 51, wherein a coating device performs physical vapor deposition or chemical vapor deposition.

Example 53 includes the subject matter of any of Examples 1-45 and further comprises a HEPA filtration system.

Example 54 includes the subject matter of any of Examples 1-45, wherein a humidistat monitor and a humidity control system are included.

Example 55 includes the subject matter of any of Examples 1-45, wherein a thermostat and a temperature control system are included.

Example 56 includes the subject matter of Example 2, wherein the nanofibers are filtered from a suspension, the suspension comprising water and nanoparticles, wherein the nanoparticles are non-permeable to the filter and form a composite layer on the surface of nanofibers.

Example 57 includes the subject matter of Examples 1-45, wherein a filtered nanofiber film has at least two areas with a different nanofiber density for each area.

Example 58 includes the subject matter of Examples 1-45 and Example 57, wherein two or more filtered nanofiber films are stacked together.

Example 59 includes the subject matter of Example 58, wherein each nanofiber film in a stack covers at least a portion of the central opening of the harvesting frame.

Example 60 includes the subject matter of Example 1-45, wherein the at least two fluid feeding lines may be combined into a single common terminal fluid feeding line, a terminus of the single common terminal fluid feeding line being placed above or inside the liquid reservoir.

Example 61 includes the subject matter of all the above Examples, wherein the nanofiber film is a nanofiber pellicle film.

Example 62 includes the subject matter of Example 61, wherein the nanofiber pellicle film is a nanofiber extreme ultraviolet lithography film (nanofiber EUV pellicle film).

### BRIEF DESCRIPTION OF THE DRAWINGS

FIG. 1 is a profile view of one embodiment of an apparatus described herein.

FIG. 2 is another profile view of another embodiment of the apparatus, as shown in FIG. 1 in a tilted status with an inclined angle (angle a).

FIG. 3 provides a flowchart illustrating processes involved in one embodiment of a method of making a nanofiber film.

The figures depict various embodiments of the present disclosure for purposes of illustration only. Numerous variations, configurations, and other embodiments will be apparent from the following detailed discussion.

### DETAILED DESCRIPTION

### Overview

Described herein are a number of techniques and apparatuses that can be used to produce nanofiber films, such as carbon nanotube films or boron nitride nanotube films. Some techniques may be suitable or unique for applications of producing ultra-thin nanofiber films. The films can have a thickness of 20 nm or less, 40 nm or less, 100 nm or less, or 250 nm or less. The films may be square, round, or other shapes. Each nanofiber film has a variety of utilities, such as filters for filtering out particles and pellicle films for extreme ultraviolet light lithography (EUVL). Each nanofiber pellicle film or EUV pellicle film may have at least one layer of ultra-thin nanotube film produced by filtration. The techniques can be fully automated, partially automated, or manual, and can be used to make different types of films and provide consistent films with repeatable composition and quality.

### Filtration

Many techniques use water or other fluids to deposit nanofibers in a random pattern or any defined pattern on a filter and in a planar orientation. The nanofibers are mixed with a fluid to form a nanofiber suspension. The fluid is allowed to pass through or is forced to pass through the filter, leaving at least one layer of nanofibers or a nanofiber film on the surface of the filter. The size, diameter, and/or shape of the nanofiber film can be defined by the size, diameter, and/or shape of the filter and the underneath openings, preferably a plurality of openings, at the bottom or floor of the reservoir structurally supporting the filter while the thickness of the nanofiber film is determined by the amount of nanofibers that are deposited on the filter. If the concentration of nanofibers dispersed in the fluid is known, the mass of nanofibers deposited onto the filter can be determined from the amount of fluid that passes through the filter. Nanofibers comprising a nanofiber film may be a mixture of different types of nanofibers. A nanotube film may be of a single type or can be a combination of two, three, or more types, for example, single-walled (single-wall), double-walled (double-wall) and/or multi-walled (multi-wall) nanotubes. If the different types of nanotubes are in the same suspension, the nanotubes are typically distributed evenly throughout the nanotube film. In other embodiments, different types of nanotubes (or other materials) may be layered on the filter by passing successive batches of suspended materials through the filter.

### Separation

The nanofiber film can be removed from the filter using any technique that does not damage the film. It has been found that a fluid, such as water, can be used to help separate the film from the filter. For instance, a fluid flow can be aimed at the interface between the nanofiber film and the filter to help loosen and remove the nanofiber film from the filter. The fluid flow can be substantially laminar and of limited velocity to avoid damaging the film while applying enough force to gently separate and remove the film from the filter. It has been found that a fluid can be essentially gravity fed to the interface and that the technique can be improved by angling the filter (and the film) in relation to the fluid flow (e.g., water) so that the fluid does not impact the film and/or the filter at a 90-degree angle. For instance, the filter can be tilted at an angle of 30° or a selected angle from a range (not limiting to the 30° angle) to allow the fluid flow to more effectively separate the film from the filter.

An alternative separation method may rely on the rising fluid surface alone, e.g., without aiming a fluid at the interface between the nanofiber film and the filter. When the rising fluid surface reaches the lowest interface point between the nanofiber film and the filter, which may be both tilted together, changes in the interface between a hydrophobic nanofiber film and a hydrophilic film rendered by the nanotube films and the fluid (e.g., water), or vice versa, start to separate the nanofiber film from the filter. The infusion of additional fluid will further separate the rest of the nanofiber film from the filter. A constant and steady infusion speed of the fluid may avoid microscopic wrinkles, tiny creases, and visible folds of the nanofiber films, especially when a nanofiber film is an ultra-thin nanotube film. After the nanofiber film is fully dislodged from the filter, it is desirable to maintain the floating nanofiber film at the surface of the fluid in a stationary position for harvesting. A harvesting step may also be initiated when a nanofiber film is close to being fully dislodged. The harvested nanofiber film can be treated, for example, by adding a metal or metal oxide coating layer (or other material) or by annealing with energy selected from various sources, to enhance nanofiber film's mechanical properties, resistance to mechanical challenges, or even chemical damages. In deep ultraviolet lithography or extreme ultraviolet lithography, a chemical damage may be a hydrogen plasma etching. The nanofiber film can then be optionally transferred from one frame to another frame or dried and/or stored using a number of processes, all the time treating the nanofiber film gently so that it is not damaged.

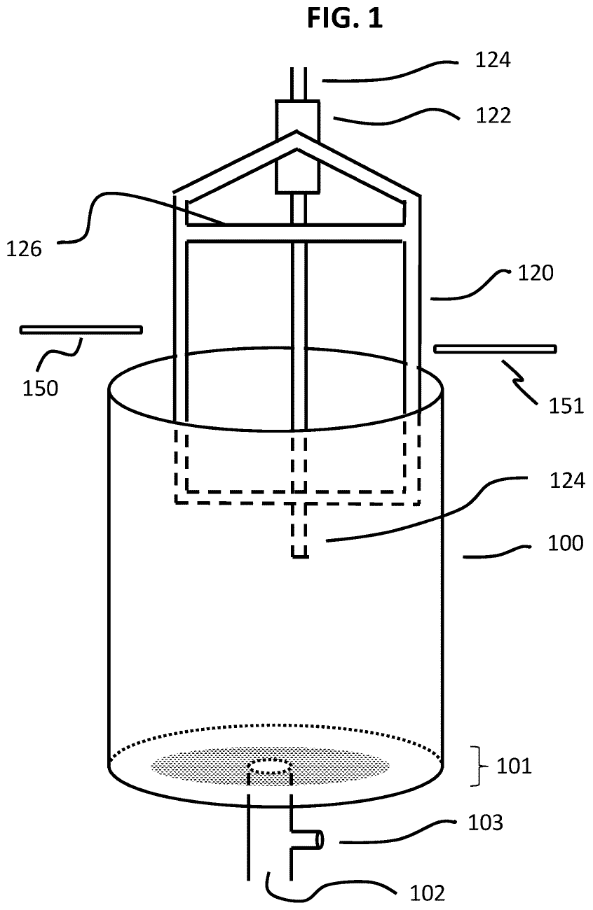

An embodiment of the present invention includes an apparatus as described in detail in FIG. 1. Reservoir 100 may be a container, which may have any shape, including a shape of a cylinder as shown or a rectangular prism (not shown). The Reservoir 100 may have a generally flat surface at its bottom or floor for filtration purposes. The bottom of Reservoir 100 may be uneven based on design or other design choices. Reservoir 100 may have an open top. Reservoir 100 may also include a plurality of Openings 101 at its bottom, which may be built-in. Reservoir 100 may have a piece of a replaceable bottom plate with a plurality of holes (Openings 101), the replaceable bottom plate being a part of or whole of the bottom. Reservoir 100 may also be provided with a Drain 102 connected to the bottom of the liquid reservoir, as shown. In FIG. 1, Drain 102, as illustrated, is connected to Openings 101 at the center of the bottom of Reservoir 100 but may be provided at other suitable positions. Openings 101 may be completely covered by a replaceable filter prior to the beginning of a filtration process to ensure even filtration flow during the process and avoid uneven distribution of non-filter permeable particles or materials passing through Openings 101 in Reservoir 100. Drain 102 may be provided with a Vacuum Connection 103 that is connected to a vacuum pressure to facilitate the filtration process. A vacuum pressure regulator (not shown) controls the supply of vacuum pressure to Drain 102. A closure (not shown) may be provided to prevent any outflow of the fluid from Reservoir 100 through Drain 102. The closure may be, for example, a valve or a slidable, pivotable, or hinged cover. Opening of closure allows fluid to pass through the replaceable filter while closing of closure prevents the flow of fluid out of Reservoir 100. The closure may be placed generally before the connection to the vacuum pressure to assist the filtration process. The replaceable filter may be a porous membrane with a fine porosity to retain nanofibers while allowing for the flow of non-nanofiber constituents of fluid therethrough. At least two fluid feeding lines may be built together (e.g., combining two lines into one line with an internal divider to keep two different fluids individually or merging two lines into a common line having a common terminus) or separately and placed over or into Reservoir 100, providing fluid communication between the interior and exterior of Reservoir 100. Tubes 150 and 151 schematically demonstrate end portions of the at least two fluid feeding lines. They may be external to Reservoir 100, with their outlets positioned over the open top of Reservoir 100. Alternatively, they may be built into the wall of Reservoir 100. Different embodiments may include zero, one, two, three, or more nozzles within one fluid feeding line or two or more fluid feeding lines. Fluid may be provided gently with minimal disturbance to the film floating on the surface of the fluid and/or filtration process. For instance, fluid can be provided at flow rates of greater than 0.01, 0.1, 1, 2, 5, or 10 liters per minute while maintaining a linear velocity into the reservoir of less than 10, less than 5, less than 1, or less than 0.5 cm/s. The velocity of the fluid flow may vary during the reservoir refilling process and nanofiber film separation process. The fluid feeding lines may be positioned so that fluid flows through the orifices directly into the container of Reservoir 100 or downward along the inner surface of Reservoir 100.

One of the at least two fluid feeding lines may carry a nanofiber suspension, while the second fluid feeding line may perform fluid infusion. The infusion fluid may be any suitable liquid, including but not limited to water.

The at least two fluid feeding lines, carrying a nanofiber suspension or an infusion fluid, respectively, may be combined into a single common terminal fluid feeding line, a terminus of the single common terminal fluid feeding line being placed above or inside Reservoir 100.

After a layer of nanotubes is formed on a filter that covers Opening 101, the nanofiber film may be separated from the filter and transferred out from Reservoir 100.

The nanofiber film may be separated from the filter by peeling it off the filter, which can be aided by the flow of a fluid. For example, the fluid flow can be reversed through the filter so that the membrane is pushed upwardly off of the filter.

In a preferred embodiment, a fluid is flowed between the filter and the nanofiber film to dislodge the nanofiber film from the filter while the bottom of Reservoir 100 maintains its horizontal level or is tilted to an inclined angle (<90°) facing the incoming direction of the fluid flow. The flow of the fluid may separate the nanofiber film from the filter. However, this approach may increase the risk of damaging a layer of nanofiber film, especially an ultra-thin nanotube film. The nanofiber film may stay on the top of the fluid surface and float to the top of Reservoir 100 with a rising fluid surface level.

By tilting the floor of the reservoir, a fluid, such as water, may flow down to the floor of Reservoir 100 along the interior wall of Reservoir 100. Other means may be provided to refill Reservoir 100 gently and/or continuously to separate the nanofiber film from the filter starting from the lowest point of the nanofiber film until a complete separation. The nanofiber film may be maintained on the surface of the fluid for the next harvesting step.

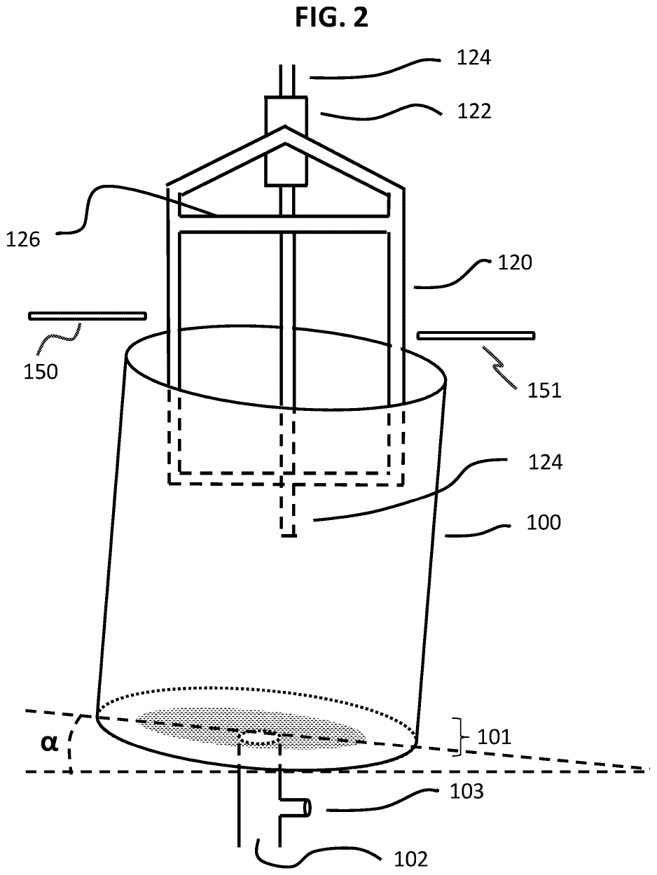

Reservoir 100 may be tilted by pivoting the Reservoir 100 on one edge. The tilting of the Reservoir 100 may be done manually, mechanically, or automated. The angle between the floor surface of Reservoir 100 (or the filter or the nanofiber film) and the horizontal is referred to as the tilt angle (angle α), as shown in FIG. 2. This angle may be referred to as an inclined angle herein. Tilt angles may be equal to or greater than 3°, equal to or greater than 5°, equal to or greater than 10°, equal to or greater than 15°, equal to or greater than 20°, equal to or greater than 25°, or equal to or greater than 30°. In these and other embodiments, the tilt angle can be equal or less than 60°, equal or less than 50°, equal or less than 40°, or equal or less than 30°.

Separation of a nanofiber film from a filter may require dipping the nanofiber film on the filter into a fluid. Reservoir 100 may be refilled with a fluid to a satisfactory level before the start of separation. Another reservoir with a suitable size and shape may also be selected as a substitute. Fluid may be the same used during the filtration or may be different. During this process, the filter may form an angle from the horizontal plane, similar to the angle a shown in FIG. 2. This angle may be equal to or greater than 3 , equal to or greater than 5°, equal to or greater than 10°, equal to or greater than 15°, equal to or greater than 20°, equal to or greater than 25°, or equal to or greater than 30°. In these and other embodiments, the tilt angle can be equal or less than 90°, equal or less than 50°, equal or less than 40°, or equal or less than 30°. Separation starts when the lowest point of a nanofiber film touches the surface of the fluid and continues until a full dislodge of the nanofiber film from the filter. Separation may progress at a controlled and/or even pace to avoid possible damage, fold, or crease to the nanofiber film. A nanofiber film is ready for harvesting when the film is completely or almost separated from the filter.

### Harvesting

FIG. 1 also includes Harvesting Frame 120, Harvesting Frame Holder (122), and Harvesting Frame Holder Track 124.

Harvesting Frame Holder 122 holds Harvesting Frame 120 in a vertical position or with an angle ranging from 30 degrees to 150 degrees from horizontal.

The lower portion of Harvesting Frame Holder Track 124 is shown in FIG. 1, with a gap between its terminus and the bottom of Reservoir 100. The lower portion of the track is preferably straight to guide upward and downward movements of Harvesting Frame Holder 122.

Harvesting Frame Holder 122 may also move horizontally to assist an initial attachment of the nanotube film to the topside of Harvesting Frame 120 (shown as 126).

FIG. 2 illustrates an exemplary embodiment of the cylinder shown in FIG. 1. The cylinder is in a tilted position with the inclined angle a, ready to separate a nanofiber film from a filter.

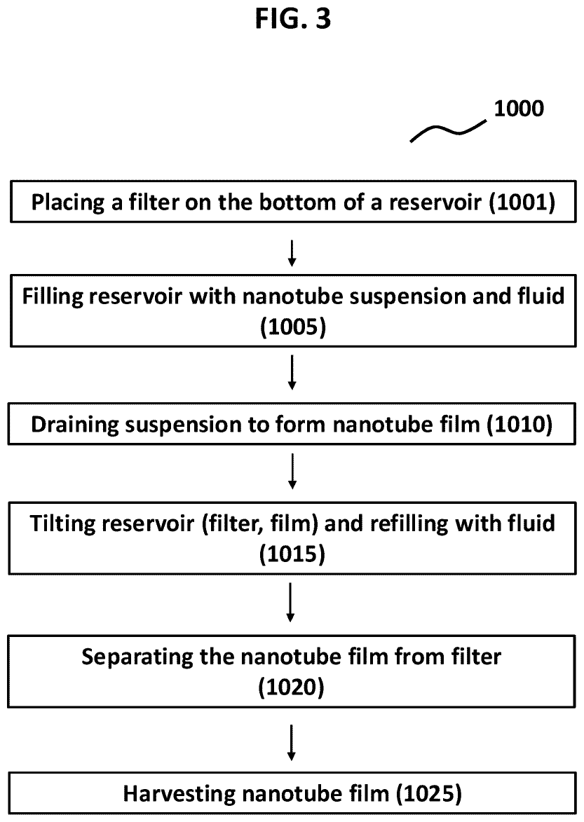

FIG. 3 provides a flow chart that illustrates one embodiment of Method 1000 for producing a filtered nanofiber film. The apparatus used is similar or identical to that described herein and can be mounted on a surface at any level or optionally at arm or eye level for easy monitoring.

Process 1001 in Method 1000 is to place a porous filter on the bottom of a reservoir. The selected filter should be non-permeable to nanofibers and optionally desired nanoparticles. The selected filter should be permeable to a fluid, optionally a surfactant of choices, and any undesirable particles. The filter may cover all holes or openings on the bottom of the reservoir to allow an even flow and self-leveling process of nanofibers during the filtration process.

Process 1005 provides a source of nanofibers for the production of a nanotube film. In this example, Process 1005 includes providing a fluid (e.g., water) and a suspension of carbon nanotubes (CNTs), boron nitride nanotubes (BNNTs), graphene, any graphene derivative, or a nanofiber of choice in a fluid carrier. Such a suspension may further include nanoparticles between 1 nm and 100 nm, 1 nm and 1 μm, or 100 nm and 2.5 μm of sizes in a variety of shapes, such as spheres, rods, cubes, and any other geometries. Common nanoparticles may include but are not limited to metal, metal particles (Au, Ag, Pt), metal oxides, polymers, colloidal polymers, and biopolymers.

For nanotubes, they can be single-walled, double-walled, multi-wall, or mixtures thereof. In one embodiment, the suspension can be prepared by first mixing nanotube powder with an aqueous solution. A surfactant may be optionally added to the suspension. Centrifuge the suspension of nanotubes and surfactant to remove nanotube aggregate. Collect and save the supernatant as a nanotube suspension or a nanotube suspension stock. Water may be added to prepare a nanotube suspension stock of a pre-determined final concentration.

The filtered nanofiber film can be formed by passing this nanofiber suspension through a filter of an appropriate size to capture the nanofibers while allowing liquid and surfactant in the suspension and the suspension diluting fluid to pass through (Process 1010). The amount of suspension to be filtered is determined by the concentration of nanofibers in the suspension and the desired density of the final filtered nanofiber film. The final filtered nanofiber film density is critical for an ultra-thin filtered film. An exemplary density may be less than 8.0 μg of carbon nanotube deposited in an area of 1.0 cm² (8.0 μg/cm²), preferably less than 3.0 μg/cm², less than 0.65 μg/cm², or higher than 0.10 μg/cm². The amount of material passing through the filter can vary from a few milliliters to many liters of fluid depending on the amount of nanofibers to be deposited. In some cases, equal to or greater than 10 mL, equal to or greater than 50 mL, equal to or greater than 100 mL, equal to or greater than 1.0 L, or equal to or greater than 10 L of suspension is passed through the filter. The volumetric rate at which the suspension (filtrate) passes through the filter can be equal to or greater than 100 μl/s, equal to or greater than 1.0 ml/s, equal to or greater than 5.0 ml/s, equal to or greater than 10 ml/s, equal to or greater than 100 ml/s, equal to or less than 200 ml/s, equal to or less than 100 ml/s, equal to or less than 10 ml/s, or equal to or less than 1.0 ml/s. The filtrate generally refers to any material or substances or a mixture passing through a filter. The filtrate in one of the embodiments of this disclosure may be selected from, but not limited to, a nanofiber suspension, a concentrated nanofiber suspension or its stock, a fluid for diluting any nanofiber suspension, one or more nanoparticles, one or more surfactants, or a combination thereof. The filtrate, once passed through the filter, may be disposed of or can be recycled to make another suspension of nanofibers or reused in forming filtered films.

The filter (or at least its upper surface) can be hydrophilic in nature or hydrophilically treated as the nanofiber film is inherently hydrophobic. Hydrophilic treatments include, for example, O₂ plasma, corona treatment, O₃ treatment, or other means to increase the hydrophilicity of a filter surface.

After the reservoir has been drained of suspension, the reservoir is tilted (Process 1015), and water is added to the reservoir for refilling. Process 1020 of separating the nanofiber film from the filter may follow.

Refilling raises the fluid level, which may dislodge the newly formed nanofiber film and then floats the nanofiber film on the surface of the fluid as the fluid continues refilling the reservoir. For example, the refilling may be accomplished by controlling the rate at which fluid is added to the reservoir, thereby controlling the floating of the nanofiber film on the surface of the fluid.

To facilitate dislodging, a flow of the fluid may be aimed at the interface of the nanofiber film and the filter.

To further facilitate dislodging, the filter or the reservoir may be tilted with an inclined angle equal to or greater than 3 degrees from horizontal during the fluid refiling process. The rising fluid surface may start to dislodge the nanofiber film from the filter at the nanofiber film's lowest point when tilted. Further refilling may eventually separate the nanofiber film from the filter completely and raise the nanofiber film to the upper portion of the reservoir for final harvesting (Process 1025).

The newly formed nanofiber film on the filter may be dipped into a fluid with an angle from horizontal, whose range is equivalent to the tilting angle of the reservoir. This gradual dipping process may separate the nanofiber film from the filter, starting from the nanofiber film's lowest point until complete or close to complete separation for the next harvesting step (Process 1025).

Accessories may be added (not shown) to overlay two or more layers of filtration-produced nanofiber films to produce pellicle films.

To eliminate possible particle contaminations of any nanotube films, a HEPA filter and/or a filtration system may be incorporated into the nanotube film production system and method.

For humidity control, a humidistat and humidity control subsystem are optionally included.

To further ensure the consistent quality and mechanical strength of the produced nanofiber films, a thermostat and temperature control system may be included to control the air temperature and/or fluid temperature.

### Add-On Devices

One of the embodiments of the present disclosure includes at least one nanofiber analytical device or instrument.

Another embodiment of the present disclosure includes at least one nanofiber sheet analytical device or instrument.

Yet another embodiment of the present disclosure includes, but is not limited to, nanofiber film treatment or adjustment devices and methods of treating the nanofiber film.

A nanofiber film analytical device, treatment device, or adjustment instrument may be a standalone device. Two or more devices selected from analytical devices, treatment devices, and adjustment instrument(s) may be combined and incorporated into a single large device or system. Further connections of these devices, described herein, by engineering principles, enable a roll-to-roll process and create a possible system or two or more subsystems with high adaptability, flexibility, easy operation, durability, and sustainability for high-volume manufacturing.

One of the exemplary devices is a light transmission measuring device. It emits light with a wavelength selected from 1 nm to 1 mm as an incident light. It has a detector in the path of the emitted light, either direct path or reflected path, to quantify the amount of the light passed through a nanofiber film (transmission light). The ratio between the transmission light intensity and incident light intensity is expressed in a percentage as a light transmission rate.

Multiple transmission rates may be obtained by taking many measurements across a nanofiber film. They can be used to generate a light transmission map to demonstrate the film density evenness or variation using an analytic tool(s) or software. A film density variation may be expressed as a percentage or other data format by taking maximum, minimum, average, and median light transmission values and repeats of individual values into consideration. A film porosity may be detected by a known device and method and adjusted.

Light scattering of a nanofiber film may be measured alone or together with the light transmission test. For nanofiber films serving the extreme ultraviolet (EUV) lithography application, EUV scattering of an EUV pellicle film is measured at a 4.7-degree angle according to the current industry standard. EUV scattering or other light scatterings may be measured at different angles ranging from −90 degrees to +90 degrees.

Another embodiment of the present disclosure includes one or more devices to measure nanofiber film mechanical strength and Young's modulus. Based on the results, nanofiber film properties may be adjusted by a separate device to stretch the nanofiber film in at least one direction to fine-tune the film's mechanical strength while maintaining the film's intactness.

Electrical resistance of a nanofiber film may be quantified by a known method and a known apparatus.

A Raman spectrometer, a Fourier-transform infrared spectrometer, UV-Vis spectrometer, or a combination thereof may be included to determine additional nanofibers' and nanofiber films' physical and chemical properties, which is a well-known methodology.

Another one of the embodiments is a nanofiber film deflection measuring device or a bulge test apparatus. In this test, a nanofiber film is attached to a flat surface of a border, and a baseline of the nanofiber film is established. An initial stream of any gas, preferably inert gas, may be applied at a low steady pressure aiming perpendicularly at the nanofiber film's central region to raise the nanofiber film's central portion. A distance between the highest tip of the deflected film from the baseline is measured and recorded as deflection. A flow rate or flow pressure of an applied gas may increase during the test until the nanofiber film ruptures (a rupture test), and a rupture gas pressure or flow rate is recorded. Applied gas pressure may have a value of 2 Pascal (2 Pa), less than 10 Pa, or less than 20 Pa. A flow rate of a gas may be expressed in mbar/second or sccm in a value selected from less than 5 mbar/second, less than 3.5 mbar/second, less than 10 sccm, or less than 8 sccm.

Nanofiber film deflection property may be adjusted according to the then industry standard by one or more apparatuses or methods, including but not limited to heating, cooling, mechanical stretching, or by electric current, energy convection, conduction, or radiation of an electromagnetic wavelength.

An annealing apparatus may be incorporated as one of the embodiments for general nanofiber film cleaning purposes or for EUV transmission enhancement purposes. An annealing device may apply an electric current, a laser, an infrared, or a microwave energy source, or a convection or radiation of an electromagnetic wavelength from 10 nm to 1 mm.

The annealing process is performed at a selected temperature or temperature range under a vacuum or an inert gas environment. The annealing temperature may be selected from a range of 50° C. to 3,000° C. A common inert gas applicable for the annealing may include but is not limited to nitrogen, argon, helium, xenon, or a combination thereof.

A nanofiber film may be coated by a nanoparticle or treated with a gas using a then-known coating apparatus or gas chamber to enhance the nanofiber film's lifetime.

The nanoparticle may comprise a metal or metal oxide selected from, but not limited to, Au, Ag, Zr, Mo, Ru, Pt, Cr, W, Cr, Ni, Co., or a combination thereof.

The nanoparticle may further comprise O, N, Si, H, SiC, or a combination thereof.

The gas may be selected from methane, ethane, ethene, propane, propene, or a combination thereof.

A coating device may perform a physical vapor deposition or chemical vapor deposition (CVD). Exemplary deposition method includes, but not limited to, electron-beam deposition, evaporative deposition, sputter deposition, thermal laser epitaxy, sublimation method, plasma-enhanced CVD, microwave-assisted CVD, and atomic layer deposition (ALD).

A particle counting device may be included to measure elemental values to determine potential undesirable particles or contaminants at any time during the production of nanofiber films to meet stringent EUV lithography pellicle requirements.

Another embodiment of the present disclosure also includes a nanofiber film-transferring apparatus. An exemplary transfer device includes a receptive frame and mechanics to accept a nanofiber film from a donor film. An exemplary transfer method comprises attaching a donor film on a first frame to a second frame and then removing the first frame and excess nanofiber film by physical or laser cutting. The transfer method may optionally apply an adhesive or an adhesive with low adhesion force on the surface of the second frame.

One embodiment of the present disclosure further includes a nanofiber film dryer to perform air drying, heat drying, radiation drying, or a combination thereof.

### Useful Nanotubes and Properties of Filtered Films

Carbon nanofiber structures are generally formed from at least one of multi-wall carbon nanotubes (MWCNT), double-walled carbon nanotubes (DWCNT), or single-walled carbon nanotubes (SWCNT). Analogs to carbon nanotubes, boron nitride nanotubes (BNNT) also exist. Other forms of nanofibers may include coaxial carbon nanotubes, conical carbon nanotubes, closed carbon nanotubes, etc. The processes used to form pure multi-wall carbon nanotubes (e.g., carbon nanotubes having from 3 to 20 concentric walls and a diameter ranging from 4 nm to 100 nm or above), double-walled carbon nanotubes (e.g., carbon nanotubes having two concentric walls and a diameter of from 1.6 nm to 6 nm), and single wall carbon nanotubes (e.g., 1 wall and a tube diameter of from 0.2 nm to 4 nm) can differ from one another. For example, while multi-wall carbon nanotubes can be fabricated using a chemical vapor deposition process on a relatively thick layer of catalyst (e.g., from 10 nm to several microns thick) on a substrate, double and single-walled carbon nanofibers are often formed using laser ablation, carbon arc processes, or chemical vapor deposition (using, e.g., acetylene, ethane as precursors) on a layer of catalyst that is thin (e.g., 0.2 nm to 10 nm thick) and which may be discontinuous across the substrate. Laser ablation generally produces shorter carbon nanotubes than those produced by chemical vapor deposition and may produce nanotubes with fewer crystallographic defects. For at least this reason, generally, the processes used to produce one type of nanofiber do not produce measurable amounts of the other types of nanofibers.

Each of these three different types of carbon nanotubes has different properties. In one example, double-walled carbon nanotubes and single-walled carbon nanotubes can be more conveniently dispersed in a solvent (i.e., with the majority of nanotubes suspended individually and not adsorbed onto other nanotubes) for subsequent formation into a sheet of randomly oriented carbon nanotubes. This ability of individual nanotubes to be uniformly dispersed in a solvent can, in turn, produce a dimensionally uniform nanotube film formed by removing the solvent from the suspended nanofibers. This configuration of a nanofiber sheet is referred to as a filtered film. This physical uniformity (further improved by stacking multiple filtered films on one another) can also improve the uniformity of the properties across the film (e.g., transparency to radiation).

The strength of van der Waals attraction between nanofibers also differs between single and/or double-walled nanofibers and multi-wall nanofibers. Generally, single and/or double-walled nanofibers have a greater van der Waals attraction to each other than that observed for multi-wall nanofibers. This increased attraction between single and/or double-walled nanofibers can improve the ability of single-and/or double-walled carbon nanotubes to adhere to one another to form a coherent nanofiber structure, such as a filtered film. The sheets or films formed from single-walled carbon nanotubes and/or Double-walled carbon nanotubes are able to better conform to topographies of an underlying surface at smaller dimensions than sheets or films formed from multi-wall carbon nanotubes. In some examples, sheets or films formed from single-wall carbon nanotubes and/or double-walled carbon nanotubes can conform to topographies of an underlying substrate as small as 10 nm, which is at least 50% smaller than the feature size a multi-wall carbon nanotube film can conform to. In some cases, the multi-wall carbon nanotubes are more likely than single and/or double-walled nanotubes to agglomerate together and thereby produce a structurally non-uniform film that is less likely to conform and/or adhere to an underlying surface.

Filtered films, particularly those made with single and/or double-walled carbon nanotubes, also generally have greater transparency to some wavelengths of radiation. In some examples, a transmittance of incident radiation can be as high as 88%, 90%, or 95%, as high as 99%, in the visible, UV, and extreme UV ranges. In some cases, this transmittance is significantly higher than drawn sheets of multi-wall carbon nanotubes. Filtered films can serve as filters for particle removal and water filtration membranes. Ultra-thin filtered films can serve as EUV pellicle films.

### Nanofibers

As used herein, the term “nanofiber” means a fiber or tubular shape material having a diameter or thickness measured in nanometers or less than 1 μm. While the embodiments herein are primarily described as fabricated from carbon nanotubes, it will be appreciated that other carbon allotropes, whether graphene, micron or nano-scale graphite fibers and/or plates, and even other compositions of nano-scale fibers such as boron nitride nanotube may be the starting material for the techniques described herein. As used herein, the terms “nanofiber” and “nanotube” are used interchangeably and encompass both single-walled carbon nanotubes, double-walled carbon nanotubes and/or multi-wall carbon nanotubes in which carbon atoms are linked together to form a cylindrical structure. Nanofibers and nanotubes also include the corresponding boron nitride materials. In some embodiments, multi-wall carbon nanotubes, as referenced herein, have between 3 and 20 walls. Double-walled carbon nanotubes have 2 walls.

The dimensions of carbon nanotubes can vary greatly depending on the production methods used. For example, the diameter of a carbon nanotube may be from 0.4 nm to 100 nm, and its length may range from 10 μm to greater than 55.5 cm. Carbon nanotubes are also capable of having very high aspect ratios (ratio of length to diameter), with some as high as 132,000,000:1 or more. Given the wide range of dimensional possibilities, the properties of carbon nanotubes are highly adjustable or “tunable.” While many intriguing properties of carbon nanotubes have been identified, harnessing the properties of carbon nanotubes in practical applications requires scalable and controllable production methods that allow the features of the carbon nanotubes to be maintained or enhanced.

One source of carbon nanotubes is through growing a nanotube forest on a catalytic substrate. Methods of fabricating a nanofiber forest are described in, for example, PCT No. WO2007/015710, which is incorporated herein by reference in its entirety.

### Properties of Suspensions and Films

Dry carbon nanotubes can be mixed with a solvent to uniformly distribute the nanotubes in the solvent to form a suspension. Mixing can include mechanical mixing (e.g., using a magnetic stir bar and stirring plate), ultrasonic agitation (e.g., using an immersion ultrasonic probe), or other means. In some examples, the solvent can be a protic or aprotic polar solvent such as water, isopropyl alcohol (IPA), N-Methyl-2-pyrrolidone (NMP), dimethyl sulfide (DMS), and combinations thereof. In some examples, a surfactant can also be included to aid the uniform dispersion of carbon nanofibers in a solvent. Exemplary surfactants include, but are not limited to, sodium cholate, sodium dodecyl sulfate (SDS), and sodium dodecyl benzene sulphonate (SDBS). The weight percentage of surfactant in the solvent can be anywhere between 0.1 weight % to 10 wt. % of solvent. In another embodiment, a mixture of 50 wt % multi-wall carbon nanotubes and 50 wt % single-wall carbon nanotubes can be prepared and suspended in water and SDS surfactant. In another embodiment, a mixture of 25 wt % single-walled carbon nanotubes and 75 wt % double-walled carbon nanotubes can be prepared and suspended in water and SDS surfactant. In another embodiment, a mixture of 50 wt % single-walled carbon nanotubes and 50 wt % double-walled carbon nanotubes can be prepared and suspended in water and SDS surfactant. In another embodiment, a mixture of 50 wt %, up to 80%, of double-walled carbon nanotubes, and single-walled and multi-wall carbon nanotubes for the rest percentage can be prepared and suspended in water and SDS surfactant.

The concentration of nanotubes in a suspension can vary depending on the type of nanotube and the desired properties of the resulting membrane. In different embodiments, nanotube suspensions can be prepared at wt/wt concentrations of equal to or greater than 5%, equal to or greater than 1%, equal to or greater than 0.1%, equal to or greater than 100 ppm, equal to or greater than 10 ppm, or equal to or greater than 1.0 ppm. Specific ranges include 0.1 to 100 ppm, 1 to 100 ppm, 1 to 1000 ppm, and 10 to 10,000 ppm. Suspensions may be developed from masterbatches that contain high concentrations of carbon nanotubes (nanotube suspension stock). For example, a masterbatch may include, by weight, greater than or equal to 0.1%, 1%, 2%, or 3% wt/v nanotubes in a solvent. More dilute suspensions may have greater stability, and in some cases, suspensions of, for example, 100 ppm or less can remain stable for more than 1 minute, more than 1 hour, or more than 5 hours. Diluted suspensions may be produced from masterbatches using the same or different solvent from that used for the masterbatch.

In some other exemplary embodiments, a suspension material may include non-nanotube materials, other carbon-based materials, or nanofibers. These include, but are not limited to, graphene, graphene oxide, non-crystalline graphene, fullerene, various nanofibers, or any derivatives, modified or functionalized aforementioned materials. These materials are capable of forming a mesh-like interconnected network, i.e., a film, and can be prepared by commercially available equipment and robots, which are incorporated herein.

### Further Considerations

The foregoing description of the embodiments of the disclosure has been presented for the purpose of illustration; it is not intended to be exhaustive or to limit the claims to the precise forms disclosed. Persons skilled in the relevant art can appreciate that many modifications and variations are possible in light of the above disclosure.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the invention, which is set forth in the following claims.

What is claimed is:

1. An apparatus for producing a nanofiber pellicle film, the apparatus comprising:
a structural frame having a base;
a reservoir having a bottom and a plurality of openings on the bottom;
at least two fluid feeding lines with outflow termini placed inside the reservoir;
a harvesting frame holder;
a harvesting frame holder track for guiding movement of the harvesting frame holder; and
a harvesting frame controller for controlling the movement of the harvesting frame holder,
wherein
the reservoir is mounted pivotally on the base of the structural frame, and the reservoir is adjustable from horizontal to an inclined angle of at least 3 degrees,
the bottom has a drainage underneath, the drainage being in communication with the plurality of openings and being connected to a negative vacuum pressure,
a first one of the at least two fluid feeding lines is configured to fill the reservoir with a fluid;
a second one of the at least two fluid feeding lines is configured to dispense a nanofiber suspension;
the harvesting frame holder is configured to maintain a harvesting frame at an angle of 75 to 105-degree from horizontal, submerge the harvesting frame underneath a surface of the fluid, attach a nanofiber pellicle film to the harvesting frame, lift the harvesting frame upward out of the reservoir; and
the harvesting frame holder track has one end outside the reservoir and an opposite end having a straight portion longer than a length of the harvesting frame, a terminus of the opposite end being spaced apart from the bottom.

2. The apparatus of claim 1, wherein the apparatus is configured such that the dispense of the nanofiber suspension leads to a nanofiber pellicle film having a density of between 0.1 μg/cm² and 8.0 μg/cm².

3. The apparatus of claim 1, wherein the apparatus is configured such that the dispense of the nanofiber suspension leads to a nanofiber pellicle film having a thickness of less than 250 nm.

4. The apparatus of claim 1, wherein the apparatus is configured such that the dispense of the nanofiber suspension leads to a nanofiber pellicle film having a thickness of less than 40 nm.

5. The apparatus of claim 1, wherein the apparatus is configured such that the dispense of the nanofiber suspension leads to a nanofiber pellicle film having a thickness of less than 20 nm.

6. The apparatus of claim 1, wherein at least one of the at least two fluid feeding lines is attached to the structural frame.

7. The apparatus of claim 1, further comprising:
an accessory selected from a light transmission measuring device, a light transmission mapping and analysis device, a light scattering measuring device, a nanofiber pellicle film strength measuring device, a nanofiber pellicle film strength adjustment device, a nanofiber electric resistance measuring device, a nanofiber pellicle film deflection measuring device, a nanofiber pellicle film deflection adjustment device, a nanofiber pellicle film transferring device, a nanofiber pellicle film annealing device, a nanofiber pellicle film coating device, a nanofiber dryer, or a combination thereof.

8. A method of preparing a nanofiber pellicle film, the method comprising:
filtering a nanofiber suspension onto a filter in a reservoir to produce a nanofiber pellicle film on the filter, wherein the filter has a horizontal planar orientation;
tilting the filter and the nanofiber pellicle film to a second plane having an inclined angle of at least three degrees from horizontal;
filling a fluid into the reservoir;
submerging the filter and the nanofiber pellicle film in the fluid to separate the nanofiber pellicle film from the filter, and
floating the nanofiber pellicle film on a surface of the fluid, wherein
the nanofibers within the nanofiber pellicle film are randomly oriented on a filter surface in a planar orientation.

9. The method of claim 8, wherein the nanofiber suspension and the fluid comprise water.

10. The method of claim 8, wherein the nanofibers are selected from carbon nanotubes, boron nitride nanotubes, graphene, graphene oxide, or a combination thereof.

11. The method of claim 10, wherein the carbon nanotubes are selected from single-walled carbon nanotubes, double-walled carbon nanotubes, multi-wall carbon nanotubes, or a combination thereof.

12. The method of claim 8, further comprising attaching the nanofiber pellicle film to a harvesting frame and lifting the harvesting frame from the fluid surface and out of the reservoir.

13. The method of claim 12, further comprising drying the nanofiber pellicle film.

14. The method of claim 8, further comprising dispensing a nanotube suspension leading to a nanotube pellicle film having a density of between 0.1 μg/cm² and 8.0 μg/cm².

15. The method of claim 8, further comprising dispensing a nanofiber suspension leading to a nanofiber pellicle film having a thickness of less than 250 nm.

16. The method of claim 8, further comprising dispensing a nanofiber suspension leading to a nanofiber pellicle film having a thickness of less than 40 nm.

17. The method of claim 8, further comprising dispensing a nanofiber suspension leading to a nanofiber pellicle film having a thickness of less than 20 nm.
